(19) United States
(12) Patent Application Publication
(10) Pub. No.: US 2018/0175290 A1
(43) Pub. Date: Jun. 21, 2018

(54) FORMING NUCLEATION LAYERS IN CORRELATED ELECTRON MATERIAL DEVICES

(71) Applicant: ARM Ltd., Cambridge (GB)

(72) Inventors: Kimberly Gay Reid, Austin, TX (US); Lucian Shifren, San Jose, CA (US)

(21) Appl. No.: 15/383,926

(22) Filed: Dec. 19, 2016

(51) Int. Cl. H01L 45/00

(52) U.S. Cl. CPC H01L 45/10; H01L 45/146; H01L 45/147; H01L 45/1616

(57) ABSTRACT

Subject matter disclosed herein may relate to forming a nucleation layer in connection with fabrication of correlated electron materials used, for example, to perform, for example, a switching function. In embodiments, processes are described in which a metallic precursor in a gaseous form is utilized to deposit a transition metal, for example, on a conductive substrate that includes a noble metal. The conductive substrate may be exposed to a reducing agent, which may operate to convert ligands of the metallic precursor to a gaseous form. A remaining metallic portion of the precursor deposited on the noble metal may allow a correlated electron material (CEM) film to be grown over the conductive substrate.

### BACKGROUND

### Field

This disclosure relates to correlated electron devices, and may relate, more particularly, to approaches toward fabricating correlated electron devices, such as may be used in switches, memory circuits, and so forth, which may exhibit desirable impedance characteristics.

### INFORMATION

Integrated circuit devices, such as electronic switching devices, for example, may be found in a wide range of electronic device types. For example, memory and/or logic devices may incorporate electronic switches suitable for use in computers, digital cameras, smart phones, tablet devices, personal digital assistants, and so forth. Factors that relate to electronic switching devices, which may be of interest to a designer in considering whether an electronic switching device is suitable for a particular application, may include physical size, storage density, operating voltages, impedance ranges, and/or power consumption, for example. Other factors that may be of interest to designers may include, for example, cost of manufacture, ease of manufacture, scalability, and/or reliability. Moreover, there appears to be an ever-increasing need for memory and/or logic devices that exhibit characteristics of lower power and/or higher speed. However, conventional fabrication techniques, which may be well suited for certain types of memory and/or logic devices, may not be entirely suitable for use in fabricating devices that utilize correlated electron materials.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1A is an illustration of an embodiment of a current density versus voltage profile of a device formed from a correlated electron material;

FIG. 1B is an illustration of an embodiment of a switching device comprising a correlated electron material and a schematic diagram of an equivalent circuit of a correlated electron material switch;

FIGS. 2A-2C illustrate an embodiment 200 of a sub-process that attempts to form a CEM device on a conductive substrate;

FIGS. 3A-3G illustrate an embodiment of a sub-process for forming a nucleation layer on a conductive substrate utilizing gaseous precursors in an atomic layer deposition approach; and

FIG. 4 is a flow diagram of an embodiment for a process of forming a nucleation layer on a conductive substrate.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers to the context of the present disclosure.

Particular aspects of the present disclosure describe methods and/or processes for preparing and/or fabricating correlated electron materials (CEMs) films to form, for example, a correlated electron switch, such as may be utilized to form a correlated electron random access memory (CERAM) in memory and/or logic devices, for example. Correlated electron materials, which may be utilized in the construction of CERAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects. In this context, a CEM switch, for example, may exhibit a substantially rapid conductor-to-insulator transition, which may be brought about by electron correlations rather than solid state structural phase changes, such as in response to a change from a crystalline to an amorphous state, for example, in a phase change memory device or, in another example, formation of filaments in resistive RAM devices. In one aspect, a substantially rapid conductor-to-insulator transition in a CEM device may be responsive to a quantum mechanical phenomenon, in contrast to melting/solidification or filament formation, for example, in phase change and resistive RAM devices. Such quantum mechanical transitions between relatively conductive and relatively insulative states, and/or between first and second impedance states, for example, in a CEM may be understood in any one of several aspects. As used herein, the terms “relatively conductive state,” “relatively lower impedance state,” and/or “metal state” may be interchangeable, and/or may, at times, be referred to as a “relatively conductive/lower impedance state.” Similarly, the terms “relatively insulative state” and “relatively higher impedance state” may be used interchangeably herein, and/or may, at times, be referred to as a relatively “insulative/higher impedance state.”

In an aspect, a quantum mechanical transition of a correlated electron material between a relatively insulative/higher impedance state and a relatively conductive/lower impedance state, wherein the relatively conductive/lower impedance state is substantially dissimilar from the insulated/higher impedance state, may be understood in terms of a Mott transition. In accordance with a Mott transition, a material may switch from a relatively insulative/higher impedance state to a relatively conductive/lower impedance state if a Mott transition condition occurs. The Mott criteria may be defined by (n_{c})^{1/3} a≈0.26, wherein n_{c} denotes a concentration of electrons, and wherein “a” denotes the Bohr radius. If a threshold carrier concentration is achieved, such that the Mott criteria is met, the Mott transition is believed to occur. Responsive to the Mott transition occurring, the state of the CEM device changes from a relatively higher resistance/higher capacitance state (e.g., an insulative/higher impedance state) to a relatively lower resistance/lower capacitance state (e.g., a conductive/lower impedance state) that is substantially dissimilar from the higher resistance/higher capacitance state.

In another aspect, the Mott transition may be controlled by a localization of electrons. If carriers, such as electrons, for example, are localized, a strong coulomb interaction between the carriers is believed to split the bands of the CEM to bring about a relatively insulative (relatively higher impedance) state. If electrons are no longer localized, a weak coulomb interaction may dominate, which may give rise to a removal of band splitting, which may, in turn, bring about a metal (conductive) band (relatively lower impedance state) that is substantially dissimilar from the relatively higher impedance state.

Further, in an embodiment, switching from a relatively insulative/higher impedance state to a substantially dissimilar and relatively conductive/lower impedance state may bring about a change in capacitance in addition to a change in resistance. For example, a CEM device may exhibit a variable resistance together with a property of variable capacitance. In other words, impedance characteristics of a CEM device may include both resistive and capacitive components. For example, in a metal state, a CEM device may comprise a relatively low electric field that may approach zero, and therefore may exhibit a substantially low capacitance, which may likewise approach zero.

Similarly, in a relatively insulative/higher impedance state, which may be brought about by a higher density of bound or correlated electrons, an external electric field may be capable of penetrating the CEM and, therefore, the CEM may exhibit higher capacitance based, at least in part, on additional charges stored within the CEM. Thus, for example, a transition from a relatively insulative/higher impedance state to a substantially dissimilar and relatively conductive/lower impedance state in a CEM device may result in changes in both resistance and capacitance, at least in particular embodiments. Such a transition may bring about additional measurable phenomena, and claimed subject matter is not limited in this respect.

In an embodiment, a device formed from a CEM may exhibit switching of impedance states responsive to a Mott-transition in a majority of the volume of the CEM comprising a device. In an embodiment, a CEM may form a “bulk switch.” As used herein, the term “bulk switch” refers to at least a majority volume of a CEM switching a device's impedance state, such as in response to a Mott-transition. For example, in an embodiment, substantially all CEM of a device may switch from a relatively insulative/higher impedance state to a relatively conductive/lower impedance state or from a relatively conductive/lower impedance state to a relatively insulative/higher impedance state responsive to a Mott-transition. A CEM may comprise one or more transition metals, transition metal compounds, one or more transition metal oxides (TMOs), for example. A CEM may also comprise one or more rare earth elements, oxides of rare earth elements, oxides comprising one or more rare earth transitional metals, perovskites, yttrium, and/or ytterbium, or any other compounds comprising metals from the lanthanide or actinide series of the Periodic Table of the Elements, for example, and claimed subject matter is not limited in scope in this respect.

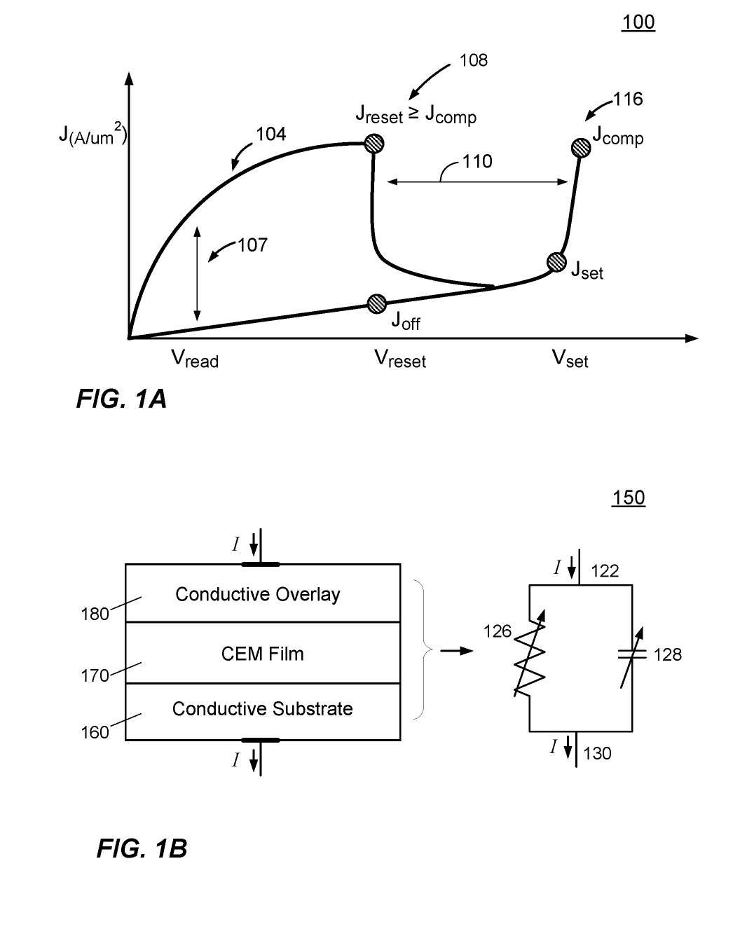

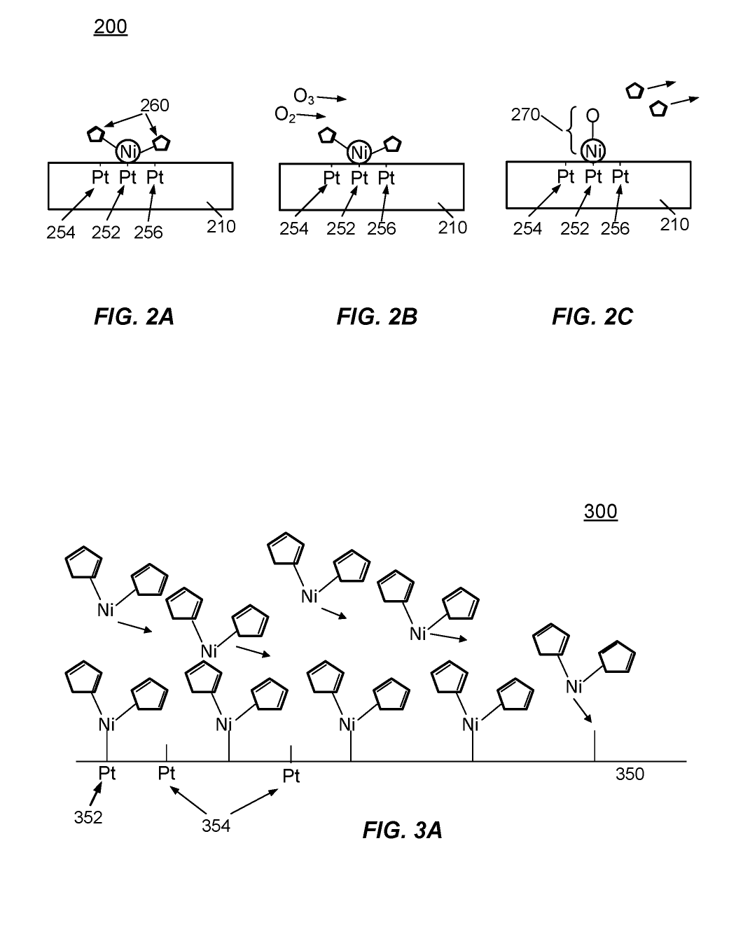

FIG. 1A is an illustration of an embodiment 100 of a current density versus voltage profile of a device formed from a correlated electron material. Based, at least in part, on a voltage applied to terminals of a CEM device, for example, during a “write operation,” the CEM device may be placed into a relatively low-impedance state or a relatively high-impedance state. For example, application of a voltage Vₛₑₜ and a current density Jₛₑₜ may bring about a transition of the CEM device to a relatively low-impedance memory state. Conversely, application of a voltage Vᵣₑₛₑₜ and a current density Jᵣₑₛₑₜ may bring about a transition of the CEM device to a relatively high-impedance memory state. As shown in FIG. 1A, reference designator 110 illustrates the voltage range that may separate Vₛₑₜ from Vᵣₑₛₑₜ. Following placement of the CEM device into a high-impedance state or a low-impedance state, the particular state of the CEM device may be detected by application of a voltage V_{read} (e.g., during a read operation) and detection of a current at terminals of the CEM device (e.g., utilizing read window 107).

According to an embodiment, the CEM device characterized in FIG. 1A may comprise any transition metal oxide (TMO), such as, for example, perovskites, Mott insulators, charge exchange insulators, and Anderson disorder insulators. In particular implementations, a CEM device may be formed from switching materials, such as nickel oxide, cobalt oxide, iron oxide, yttrium oxide, titanium yttrium oxide, and perovskites, such as chromium doped strontium titanate, lanthanum titanate, and the manganate family including praseodymium calcium manganate, and praseodymium lanthanum manganite, just to provide a few examples. In particular, oxides incorporating elements with incomplete “d” and “f” orbital shells, such as those listed above, may exhibit sufficient impedance switching properties for use in a CEM device. Other implementations may employ other transition metal compounds without deviating from claimed subject matter.

In one aspect, the CEM device of FIG. 1A may comprise other types of transition metal oxide variable impedance materials, though it should be understood that these are exemplary only and are not intended to limit claimed subject matter. Nickel oxide (NiO) is disclosed as one particular TMO. NiO materials discussed herein may be doped with extrinsic ligands, such as carbonyl (CO), which may establish and/or stabilize variable impedance properties and/or bring about a P-type operation of a CEM. As the term is used herein, “P-type” means a CEM that exhibits enhanced or increased electrical conductivity while operating in a low-impedance state, such as along region 104 of FIG. 1A, discussed herein. Thus, in another particular example, NiO doped with extrinsic ligands may be expressed as NiO:Lₓ, where Lₓ may indicate a ligand element or compound and x may indicate a number of units of the ligand for one unit of NiO. A value of x may be determined for any specific ligand and any specific combination of ligand with NiO or with any other transition metal compound by balancing valences. Other dopant ligands, which may bring about or enhance conductivity in a low-impedance state in addition to carbonyl may include: nitrosyl (NO), triphenylphosphine (PPH₃), phenanthroline (C₁₂H₈N₂), bipyridine (C₁₀H₈N₂), ethylenediamine (C₂H₄(NH₂)₂), ammonia (NH₃), acetonitrile (CH₃CN), Fluoride (F), Chloride (Cl), Bromide (Br), cyanide (CN), sulfur (S), and others.

In another embodiment, the CEM device of FIG. 1A may comprise other transition metal oxide variable impedance materials, such as nitrogen-containing ligands, though it should be understood that these are exemplary only and are not intended to limit claimed subject matter. Nickel oxide (NiO) is disclosed as one particular TMO. NiO materials discussed herein may be doped with extrinsic nitrogen-containing ligands, which may stabilize variable impedance properties. In particular, NiO variable impedance materials disclosed herein may include nitrogen-containing molecules of the form CₓH_{y}N_{z} (wherein x≥0, y≥0, z≥0, and wherein at least x, y, or z comprise values >0) such as: ammonia (NH₃), cyano (CN⁻), azide ion (N₃⁻) ethylene diamine (C₂H₈N₂), phen(1,10-phenanthroline) (C₁₂H₈N₂), 2,2′bipyridine (C₁₀,H₈N₂), ethylenediamine ((C₂H₄(NH₂)₂), pyridine (C₅H₅N), acetonitrile (CH₃CN), and cyanosulfanides such as thiocyanate (NCS⁻), for example. NiO variable impedance materials disclosed herein may include members of an oxynitride family (NₓO_{y}, wherein x and y comprise whole numbers, and wherein x≥0 and y≥0 and at least x or y comprise values >0), which may include, for example, nitric oxide (NO), nitrous oxide (N₂O), nitrogen dioxide (NO₂), or precursors with an NO₃⁻ ligand. In embodiments, metal precursors comprising nitrogen-containing ligands, such as ligands amines, amides, alkylamides nitrogen-containing ligands with NiO by balancing valences.

In accordance with FIG. 1A, if sufficient bias is applied (e.g., exceeding a band-splitting potential) and the aforementioned Mott condition is satisfied (e.g., injected electron holes are of a population comparable to a population of electrons in a switching region, for example), a CEM device may switch from a relatively low-impedance state to a relatively high-impedance state, for example, responsive to a Mott transition. This may correspond to point 108 of the voltage versus current density profile of FIG. 1A. At, or suitably near this point, electrons are no longer screened and become localized near the metal ion. This correlation may result in a strong electron-to-electron interaction potential, which may operate to split the bands to form a relatively high-impedance material. If the CEM device comprises a relatively high-impedance state, current may be generated by transportation of electron holes. Consequently, if a threshold voltage is applied across terminals of the CEM device, electrons may be injected into a metal-insulator-metal (MIM) diode over the potential barrier of the MIM device. In certain embodiments, injection of a threshold current of electrons, at a threshold potential applied across terminals of a CEM device, may perform a “set” operation, which places the CEM device into a low-impedance state. In a low-impedance state, an increase in electrons may screen incoming electrons and remove a localization of electrons, which may operate to collapse the band-splitting potential, thereby giving rise to the low-impedance state.

According to an embodiment, current in a CEM device may be controlled by an externally applied “compliance” condition, which may be determined at least partially on the basis of an applied external current, which may be limited during a write operation, for example, to place the CEM device into a relatively high-impedance state. This externally-applied compliance current may, in some embodiments, also set a condition of a current density for a subsequent reset operation to place the CEM device into a relatively high-impedance state. As shown in the particular implementation of FIG. 1A, a current density J_{comp} may be applied during a write operation at point 116 to place the CEM device into a relatively low-impedance state, which may determine a compliance condition for placing the CEM device into a high-impedance state in a subsequent write operation. As shown in FIG. 1A, the CEM device may be subsequently placed into a low-impedance state by application of a current density Jᵣₑₛₑₜ≥J_{comp} at a voltage Vᵣₑₛₑₜ at point 108, at which J_{comp} is externally applied.

In embodiments, compliance may set a number of electrons in a CEM device which may be “captured” by holes for the Mott transition. In other words, a current applied in a write operation to place a CEM device into a relatively low-impedance memory state may determine a number of holes to be injected to the CEM device for subsequently transitioning the CEM device to a relatively high-impedance memory state.

As pointed out above, a reset condition may occur in response to a Mott transition at point 108. As pointed out above, such a Mott transition may bring about a condition in a CEM device in which a concentration of electrons n approximately equals, or becomes at least comparable to, a concentration of electron holes p. This condition may be modeled according to expression (1) as follows:

$${λ}_{TF} {n}^{\frac{1}{3}} = C ∼ 0.26 \\ n = ( \frac{C}{{λ}_{TF}} ) \qquad ( 1 )$$

In expression (1), λ_{TF} corresponds to a Thomas Fermi screening length, and C is a constant.

According to an embodiment, a current or current density in region 104 of the voltage versus current density profile shown in FIG. 1A, may exist in response to injection of holes from a voltage signal applied across terminals of a CEM device. Here, injection of holes, which may be indicative of the presence of a P-type dopant, may bring about operation of a CEM device that meets a Mott transition criterion for the low-impedance state to high-impedance state transition. A state transition may occur responsive to current I_{MI} when a threshold voltage V_{MI} is applied across terminals of a CEM device. This may be modeled according to expression (2) as follows:

$${I}_{MI} ( {V}_{MI} ) = \frac{dQ ( {V}_{MI} )}{dt} \approx \frac{Q ( {V}_{MI} )}{t} \\ Q ( {V}_{MI} ) = qn ( {V}_{MI} ) \qquad ( 2 )$$

Where Q(V_{MI}) corresponds to the charged injected (holes or electrons) and is a function of an applied voltage. Injection of electrons and/or holes to enable a Mott transition may occur between bands and in response to threshold voltage V_{MI}, and threshold current I_{MI}. By equating electron concentration n with a charge concentration to bring about a Mott transition by holes injected by I_{MI} in expression (2) according to expression (1), a dependency of such a threshold voltage V_{MI} on Thomas Fermi screening length λ_{TF} may be modeled according to expression (3), as follows:

$${I}_{MI} ( {V}_{MI} ) = \frac{Q ( {V}_{MI} )}{I} = \frac{qn ( {V}_{MI} )}{t} = \frac{q}{t} {( \frac{C}{{λ}_{IF}} )}^{3} \\ {J}_{reset} ( {V}_{MI} ) = {J}_{MI} ( {V}_{MI} ) = \frac{{I}_{MI} ( {V}_{MI} )}{{A}_{CEM}} = \frac{q}{{A}_{CEM} t} {( \frac{C}{{λ}_{TF} ( {V}_{MI} )} )}^{3} \qquad ( 3 )$$

In which Δ_{CEM} is a cross-sectional area of a CEM device; and Jᵣₑₛₑₜ(V_{MI}) may represent a current density through the CEM device to be applied to the CEM device at a threshold voltage V_{MI}, which may place the CEM device into a relatively high-impedance state.

FIG. 1B is an illustration of an embodiment 150 of a switching device comprising a correlated electron material and a schematic diagram of an equivalent circuit of a correlated electron material switch. As previously mentioned, a correlated electron device, such as a CEM switch, a CERAM array, or other type of device utilizing one or more correlated electron materials may comprise variable or complex impedance device that may exhibit characteristics of both variable resistance and variable capacitance. In other words, impedance characteristics for a CEM variable impedance device, such as a device comprising a conductive substrate 160, CEM 170, and conductive overlay 180, may depend at least in part on resistance and capacitance characteristics of the device if measured across device terminals 122 and 130. In an embodiment, an equivalent circuit for a variable impedance device may comprise a variable resistor, such as variable resistor 126, in parallel with a variable capacitor, such as variable capacitor 128. Of course, although a variable resistor 126 and variable capacitor 128 are depicted in FIG. 1B as comprising discrete components, a variable impedance device, such as device of embodiment 150, may comprise a substantially homogenous CEM and claimed subject matter is not limited in this respect.

Table 1 below depicts an example truth table for an example variable impedance device, such as the device of embodiment 150.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied})~0 | Z_{low}(V_{applied}) |

In an embodiment, Table 1 shows that a resistance of a variable impedance device, such as the device of embodiment 150, may transition between a low-impedance state and a substantially dissimilar, high-impedance state as a function at least partially dependent on a voltage applied across a CEM device. In an embodiment, an impedance exhibited at a low-impedance state may be approximately in the range of 10.0-100,000.0 times lower than an impedance exhibited in a high-impedance state. In other embodiments, an impedance exhibited at a low-impedance state may be approximately in the range of 5.0 to 10.0 times lower than an impedance exhibited in a high-impedance state, for example. It should be noted, however, that claimed subject matter is not limited to any particular impedance ratios between high-impedance states and low-impedance states. Table 1 shows that a capacitance of a variable impedance device, such as the device of embodiment 150, may transition between a lower capacitance state, which, in an example embodiment, may comprise approximately zero (or very little) capacitance, and a higher capacitance state that is a function, at least in part, of a voltage applied across a CEM device.

According to an embodiment, a CEM device, which may be utilized to form a CEM switch, a CERAM memory device, or a variety of other electronic devices comprising one or more correlated electron materials, may be placed into a relatively low-impedance memory state, such as by transitioning from a relatively high-impedance state, for example, via injection of a sufficient quantity of electrons to satisfy a Mott transition criteria. In transitioning a CEM device to a relatively low-impedance state, if enough electrons are injected and the potential across the terminals of the CEM device overcomes a threshold switching potential (e.g., Vₛₑₜ), injected electrons may begin to screen. As previously mentioned, screening may operate to unlocalize double-occupied electrons to collapse the band-splitting potential, thereby bringing about a relatively low-impedance state.

In particular embodiments, changes in impedance states of CEM devices, such as changes from a low-impedance state to a substantially dissimilar high-impedance state, for example, may be brought about by “donation” and “back-donation” of electrons of compounds comprising NiₓO_{y} (wherein the subscripts “x” and “y” comprise whole numbers). As the term is used herein, “donation” means a supplying of one or more electrons to a transition metal, transition metal oxide, or any combination thereof, by an adjacent molecule of a lattice structure, for example, comprising the transition metal, transition metal compound, transition metal oxide, or comprising a combination thereof. “Back-donation” means the supplying of one or more electrons by a transition metal, transition metal oxide, or any combination thereof, to an adjacent molecule of a lattice structure. In embodiments, electron donation may permit a transition metal, transition metal compound, transition metal oxide, or combination thereof, to maintain an ionization state that brings about operation of a CEM in a high-impedance state. Back-donation, on the other hand, may permit a transition metal, transition metal compound, transition metal oxide, or a combination thereof, to maintain an ionization state that is favorable to electrical conduction under an influence of an applied voltage (e.g., low-impedance operation). In certain embodiments, electron donation and back-donation in a CEM, for example, may occur responsive to use of carbonyl (CO) or a nitrogen-containing dopant, such as ammonia (NH₃), ethylene diamine (C₂H₈N₂), or members of an oxynitride family (NₓO_{y}), for example, which may permit a CEM to exhibit a property in which electrons are controllably, and reversibly, donated to a conduction band of the transition metal or transition metal oxide, such as nickel, for example, during operation of a device or circuit comprising a CEM. Donation and back-donation in, for example, a nickel oxide material (e.g., NiO:CO or NiO:NH₃), may permit the nickel oxide material to switch between substantially dissimilar impedance properties, such as between a high-impedance property and a low-impedance property, during device operation.

Thus, in this context, an electron donating/back-donating material means a material that exhibits an impedance switching property, such as switching from a first impedance state to a substantially dissimilar second impedance state (e.g., from a relatively low impedance state to a relatively high impedance state, or vice versa) based, at least in part, on influence of an applied voltage to control donation of electrons, and reversal of the electron donation (back-donation), to and from a conduction band of the CEM.

In some embodiments, by way of back-donation, a CEM switch comprising a transition metal, transition metal compound, or a transition metal oxide, may exhibit low-impedance properties if the transition metal, such as nickel, for example, is placed into an oxidation state of 2+ (e.g., Ni²⁺ in a material, such as NiO:CO or NiO:NH₃). Conversely, electron back-donation may be reversed if a transition metal, such as nickel, for example, is placed into an oxidation state of 1+ or 3+. Accordingly, during operation of a CEM device, back-donation may result in “disproportionation,” which may comprise substantially simultaneous oxidation and reduction reactions, substantially in accordance with expression (4), below:

2Ni²⁺→Ni¹⁺+Ni³⁺ (4)

Such disproportionation, in this instance, means formation of nickel ions as Ni¹⁺+Ni³⁺ as shown in expression (4), which may bring about, for example, a relatively high-impedance state during operation of the CEM device. In an embodiment, a dopant such as a carbon-containing ligand, carbonyl (CO) or a nitrogen-containing ligand, such as an ammonia molecule (NH₃), may permit sharing of electrons during operation of a CEM device so as to give rise to the disproportionation reaction of expression (4), and its reversal, substantially in accordance with expression (5), below:

Ni¹⁺+Ni³⁺→2Ni²⁺ (5)

As previously mentioned, reversal of the disproportionation reaction, as shown in expression (5), permits nickel-based CEM to return to a relatively low-impedance state.

In embodiments, depending on a molecular concentration of NiO:CO or NiO:NH₃, for example, which may vary from values approximately in the range of an atomic percentage of 0.1% to 10.0%, Vᵣₑₛₑₜ and Vₛₑₜ, as shown in FIG. 1A, may vary approximately in the range of 0.1 V to 10.0 V subject to the condition that Vₛₑₜ≥Vᵣₑₛₑₜ. For example, in one possible embodiment, Vᵣₑₛₑₜ may occur at a voltage approximately in the range of 0.1 V to 1.0 V, and Vₛₑₜ may occur at a voltage approximately in the range of 1.0 V to 2.0 V, for example. It should be noted, however, that variations in Vₛₑₜ and Vᵣₑₛₑₜ may occur based, at least in part, on a variety of factors, such as atomic concentration of an electron donating/back-donating material, such as NiO:CO or NiO:NH₃ and other materials present in the CEM device, as well as other process variations, and claimed subject matter is not limited in this respect.

In certain embodiments, atomic layer deposition may be utilized to form or to fabricate films comprising NiO materials, such as NiO:CO or NiO:NH₃, to permit electron donation/back-donation during operation of a CEM device in a circuit environment, for example, to switch between low-impedance states and high-impedance states. In particular embodiments, atomic layer deposition may utilize two or more precursors to deposit components of, for example, NiO:CO or NiO:NH₃, or other transition metal oxide, transition metal, or combination thereof, onto a conductive substrate. In an embodiment, layers of a CEM device may be deposited utilizing separate precursor molecules, AX and BY, according to expression (6a), below:

AX_{(gas)}+BY_{(gas)}=AB_{(solid)}+XY_{(gas)} (6a)

Wherein “A” of expression (6a) corresponds to a transition metal, transition metal compound, transition metal oxide, or any combination thereof. In embodiments, a transition metal oxide may comprise nickel, but may comprise other transition metals, transition metal compound, and/or transition metal oxides, such as aluminum, cadmium, chromium, cobalt, copper, gold, iron, manganese, mercury, molybdenum, nickel palladium, rhenium, ruthenium, silver, tantalum, tin, titanium, vanadium yttrium, and zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

In embodiments, “X” of expression (6a) may comprise a ligand, such as organic ligand, comprising amidinate (AMD), dicyclopentadienyl (Cp)₂, diethylcyclopentadienyl (EtCp)₂, Bis(2,2,6,6-tetramethylheptane-3,5-dionato) ((thd)₂), acetylacetonate (acac), bis(methylcyclopentadienyl) ((CH₃C₅H₄)₂), dimethylglyoximate (dmg)₂, 2-amino-pent-2-en-4-onato (apo)₂, (dmamb)₂ where dmamb=1-dimethylamino-2-methyl-2-butanolate, (dmamp)₂ where dmamp=1-dimethylamino-2-methyl-2-propanolate, Bis(pentamethylcyclopentadienyl) (C₅(CH₃)₅)₂ and carbonyl (CO)₄. Accordingly, in some embodiments, nickel-based precursor AX may comprise, for example, nickel amidinate (Ni(AMD)), nickel dicyclopentadienyl (Ni(Cp)₂), nickel diethyl cyclopentadienyl (Ni(EtCp)₂), Bis(2,2,6,6-tetramethylheptane-3,5-dionato)Ni(II) (Ni(thd)₂), nickel acetylacetonate (Ni(acac)₂), bis(methylcyclopentadienyl)nickel (Ni(CH₃C₅H₄)₂, Nickel dimethylglyoximate (Ni(dmg)₂), Nickel 2-amino-pent-2-en-4-onato (Ni(apo)₂), Ni(dmamb)₂ where dmamb=1-dimethylamino-2-methyl-2-butanolate, Ni(dmamp)₂ where dmamp=1-dimethylamino-2-methyl-2-propanolate, Bis(pentamethylcyclopentadienyl) nickel (Ni(C₅(CH₃)₅)₂, and nickel carbonyl (Ni(CO)₄), just to name a few examples. In expression (6a), precursor “BY” may comprise an oxidizer, such as oxygen (O₂), ozone (O₃), nitric oxide (NO), hydrogen peroxide (H₂O₂), just to name a few examples. In other embodiments as will be described further herein, plasma may be used with an oxidizer to form oxygen radicals.

However, in particular embodiments, a dopant comprising an electron donating/back-donating material in addition to precursors AX and BY may be utilized to form layers of a CEM device. An additional dopant ligand comprising an electron donating/back-donating material, which may co-flow with precursor AX, may permit formation of electron donating/back-donating compounds, substantially in accordance with expression (6b), below. In embodiments, a dopant comprising an electron donating/back-donating material, such as ammonia (NH₃), methane (CH₄), carbon monoxide (CO), or other material may be utilized, as may other ligands comprising carbon or nitrogen or other dopants comprising electron donating/back-donating materials listed above. Thus, expression (6a) may be modified to include an additional dopant ligand comprising an electron donating/back-donating material substantially in accordance with expression (6b), below:

AX_{(gas)}+(NH₃ or other ligand comprising nitrogen)+BY_{(gas)}=AB:NH_{3(solid)}+XY_{(gas)} (6b)

It should be noted that concentrations, such as atomic concentration, of precursors, such as AX, BY, and NH₃ (or other ligand comprising nitrogen) of expressions (6a) and (6b) may be adjusted so as to bring about a desired atomic concentration of nitrogen or carbon dopant comprising an electron donating/back-donating material in a fabricated CEM device. In certain embodiments, a dopant in the form of ammonia (NH₃) or carbonyl (CO) comprising an atomic concentration of between approximately 0.1% and 15.0% may bring about electron donation/back-donation in a CEM material. However, claimed subject matter is not necessarily limited to the above-identified precursors and/or atomic concentrations of donating/back-donating materials such as nitrogen-containing or carbon-containing dopants. Rather, claimed subject matter is intended to embrace all such precursors and dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, or the like, utilized in fabrication of CEM devices. In expressions (6a) and (6b), “BY” may comprise an oxidizer, such as oxygen (O₂), ozone (O₃), nitric oxide (NO), hydrogen peroxide (H₂O₂), just to name a few examples. In other embodiments, plasma may be used with an oxidizer (BY) to form oxygen radicals. Likewise, plasma may be used with the doping species comprising an electron donating/back-donating material to form an activated species to control the doping concentration of a CEM.

In particular embodiments, such as embodiments utilizing atomic layer deposition, a conductive substrate may be exposed to precursors, such as AX and BY, as well as dopants comprising electron donating/back-donating materials (such as ammonia or other ligands comprising metal-nitrogen bonds, including, for example, nickel-amides, nickel-imides, nickel-amidinates, or combinations thereof) in a heated chamber, which may attain, for example, a temperature approximately in the range of 20.0° C. to 1000.0° C., for example, or between temperatures approximately in the range of 20.0° C. and 500.0° C. in certain embodiments. In one particular embodiment, in which atomic layer deposition of NiO:NH₃, for example, is performed, chamber temperature ranges approximately in the range of 20.0° C. and 400.0° C. may be utilized. Responsive to exposure to precursor gases (e.g., AX, BY, NH₃, or other ligand comprising nitrogen), such gases may be purged from the heated chamber for durations approximately in the range of 0.5 seconds to 180.0 seconds. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression 6(a)) or a single three-precursor cycle (e.g., AX, NH₃, CH₄, or other ligand comprising nitrogen, carbon or other dopant comprising an electron donating/back-donating material, and BY, as described with reference to expression 6(b)) utilizing atomic layer deposition may bring about a CEM device layer comprising a thickness approximately in the range of 0.6 Å to 5.0 Å per cycle). Accordingly, in an embodiment, to form a CEM device film comprising a thickness of approximately 500.0 Å utilizing an atomic layer deposition process in which layers comprise a thickness of approximately 0.6 Å, 800-900 cycles, for example, may be utilized. In another embodiment, utilizing an atomic layer deposition process in which layers comprise approximately 5.0 Å, 100 two-precursor cycles, for example. It should be noted that atomic layer deposition may be utilized to form CEM device films having other thicknesses, such as thicknesses approximately in the range of 1.5 nm and 150.0 nm, for example, and claimed subject matter is not limited in this respect.

In particular embodiments, responsive to one or more two-precursor cycles (e.g., AX and BY), or three-precursor cycles (AX, NH₃, CH₄, or other ligand comprising nitrogen, carbon or other dopant comprising an electron donating/back-donating material and BY), of atomic layer deposition, a CEM device film may undergo in situ annealing, which may permit improvement of film properties or may be used to incorporate a dopant comprising an electron donating/back-donating material, such as in the form of carbonyl or ammonia, in the CEM device film. In certain embodiments, a chamber may be heated to a temperature approximately in the range of 20.0° C. to 1000.0° C. However, in other embodiments, in situ annealing may be performed utilizing chamber temperatures approximately in the range of 100.0° C. to 800.0° C. In situ annealing times may vary from a duration approximately in the range of 1.0 seconds to 5.0 hours. In particular embodiments, annealing times may vary within more narrow ranges, such as, for example, from approximately 0.5 minutes to approximately 180.0 minutes, for example, and claimed subject matter is not limited in these respects.

In particular embodiments, a CEM device manufactured in accordance with the above-described process may exhibit a “born on” property in which the device exhibits relatively low impedance (relatively high conductivity) immediately after fabrication of the device. Accordingly, if a CEM device is integrated into a larger electronics environment, for example, at initial activation a relatively small voltage applied to a CEM device may permit a relatively high current flow through the CEM device, as shown by region 104 of FIG. 1A. For example, as previously described herein, in at least one possible embodiment, Vᵣₑₛₑₜ may occur at a voltage approximately in the range of 0.1 V to 1.0 V, and Vₛₑₜ may occur at a voltage approximately in the range of 1.0 V to 2.0 V, for example. Accordingly, electrical switching voltages operating in a range of approximately 2.0 V, or less, may permit a memory circuit, for example, to write to a CERAM memory device, to read from a CERAM memory device, or to change state of a CERAM switch, for example. In embodiments, such relatively low voltage operation may reduce complexity, cost, and may provide other advantages over competing memory and/or switching device technologies.

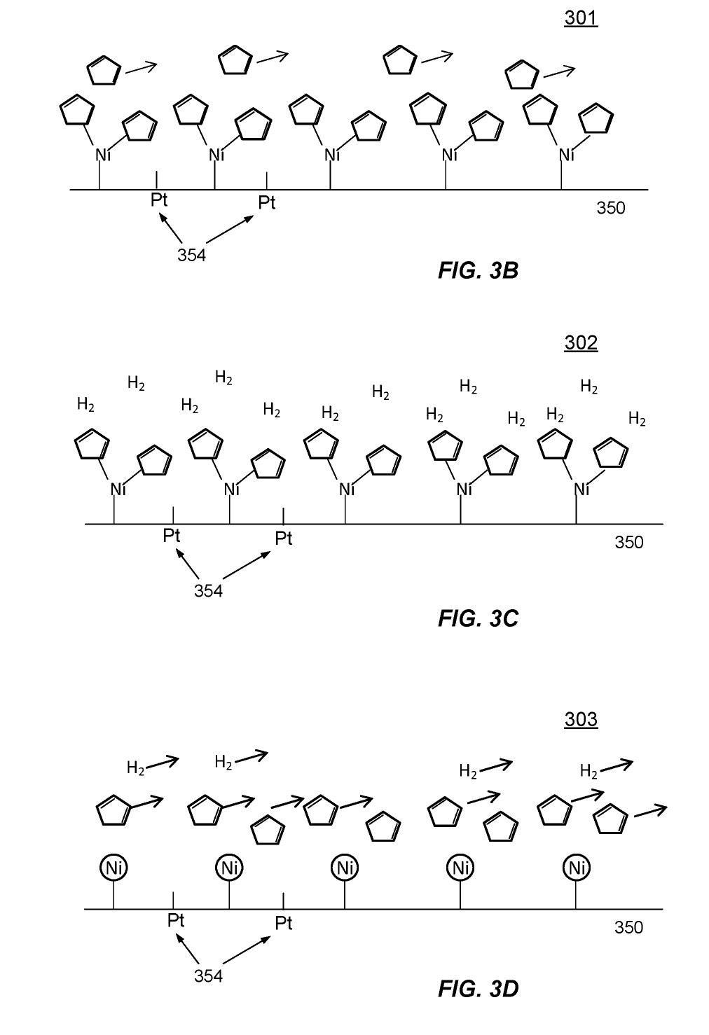

FIGS. 2A-2C illustrate an embodiment 200 of a sub-process that attempts to form a CEM device on a conductive substrate. In FIG. 2A, conductive substrate 210 may comprise a noble metal that resists oxidation. As the term is used herein, a “noble metal” means an oxidation-resistant metal, an oxidation-resistant metal alloy comprising an atomic concentration of a noble metal, or an oxide of at least one noble metal that is sufficient to bring about predominantly conductive behavior of the metal. In embodiments, predominantly conductive behavior may be brought about by a material comprising at least 50.0% noble metal or a material comprising at least 50.0% of an alloy of two or more noble metals. Predominantly conductive behavior may additionally be brought about by a material formed from an oxide of at least one noble metal. For example, noble metals, alloys of noble metals, and oxides of at least one noble metal exhibiting predominantly conductive behavior may comprise at least 50.0% of Ruthenium (Ru), rhodium (Rh), palladium (Pd), silver (Ag), osmium (Os), iridium (Ir), platinum (Pt), gold (Au) or mercury (Hg), or any combination thereof. In view of a noble metal's resistance to oxidation, a surface-dominated reaction, such as atomic layer deposition (previously described with reference to expressions (6a) and (6b)) may be problematic to induce.

For example, if conductive substrate 210 comprises an atomic concentration of greater than 50.0% of platinum, for example, formation of an initial layer of nickel oxide on a surface of substrate 210 may be difficult to achieve. In embodiments, an oxide layer, such as a nickel oxide layer, for example, may permit deposition of layers of CEM to be deposited on the initial layer of nickel oxide so as to bring about the layer-by-layer formation of a CEM film as described with reference to expressions (6a) and (6b). Accordingly, in this context, a CEM film means one or more layers of correlated electron material, which may be built by atomic layer deposition to deposit one or more layers having a thickness of at least a single atom on or over a conductive substrate, or utilizing any other suitable process, that exhibits a capability to switch between high-impedance operation and low-impedance operation as described herein. In one nonlimiting example, such as illustrated in FIG. 2A, for example, in which atomic layer deposition is utilized to form a CEM film, substrate 210 may be exposed to a precursor, such as gaseous nickel dicyclopentadienyl (Ni(Cp)₂. In accordance with an atomic layer deposition process, substrate 210 may adsorb a small amount of precursor, such as, for this example, Ni(Cp)₂, by forming metal-to-metal bonds between Ni atoms and at least some Pt atoms. In FIG. 2A, such metal-to-metal bonds between Ni atoms and at least some Pt may be represented by Pt atom 252, shown bonded to a Ni atom of a Ni(Cp)₂ molecule.

However, in embodiment 200, adsorption of Ni(Cp)₂ may allow Cp ligands to shield or otherwise obstruct access by gaseous precursors to a significant percentage of Pt sites. Accordingly, as shown in FIG. 2A, Pt atoms 254 and 256 are shown as being disposed under, and shielded by, Cp ligands 260. As shown in FIG. 2B, responsive to oxidation of Ni(Cp), such as by way of exposure of adsorbed Ni(Cp)₂ to oxygen (O₂), ozone (O₃), or other oxidizing agent, Cp ligands may be chemically reduced and, consequently, permitted to detach from Ni atoms adsorbed by conductive substrate 210. In embodiments, such separation of Cp from Ni atoms, as shown in FIG. 2C, for example, may bring about formation of NiO, as indicated by NiO molecule 270, but may also result in a large percentage of unreacted Pt atoms, such as Pt atoms 254 and 256, for example, at a surface of conductive substrate 210. Additionally, at least in some embodiments, increasing a concentration of a precursor gas, such as (Ni(Cp)₂, may not bring about increased metal-to-metal bonding Ni and Pt atoms. Further, in particular embodiments, despite repeated exposure of conductive substrate 210, which comprises a large proportion of a noble metal (e.g., a substrate comprising an atomic concentration of at least 50.0% noble metal or a noble metal oxide comprising an atomic concentration of at least 50.0% metal), a large percentage of unreacted Pt sites at a surface of conductive substrate 210 may remain.

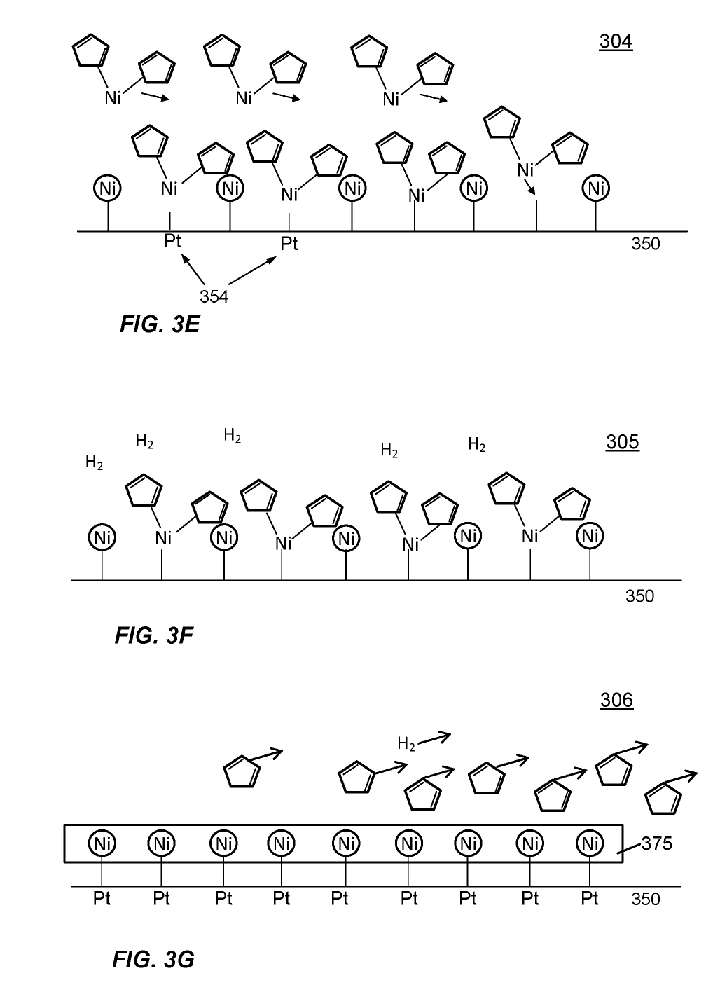

Thus, as pointed out with reference to FIGS. 2A-2C, formation of an initial layer of a transition metal (e.g., Ni) or a transition metal oxide on a conductive substrate comprising a large proportion of a noble metal may be difficult to achieve. Hence, FIGS. 3A-3G illustrate an embodiment of a sub-process for forming a nucleation layer on a conductive substrate utilizing gaseous precursors via an atomic layer deposition approach. As the term is used herein, a “nucleation layer” means a layer of material that permits deposition of a CEM film on a conductive substrate by way of a chemical and/or physical process. For example, a nucleation layer may comprise a layer of material, such as a conductive material, that permits deposition, for example, of a transition metal or a metal selected from the lanthanide series or the actinide series of the periodic table of the elements, over a substrate via a process, such as atomic layer deposition, metal oxide chemical vapor deposition, physical vapor deposition, or other fabrication process. As described with reference to FIGS. 3A-3G, a nucleation layer may be formed on a conductive substrate comprising an atomic concentration of at least 50.0% noble metal or a noble metal oxide comprising an atomic concentration of at least 50.0% metal (e.g., Pt, Ru, Rh, Pd, Ag, Os, Ir, Au or Hg, or any combination thereof including metal oxides). A nucleation layer may bring about other advantageous effects, and claimed subject matter is not limited in this regard.

As shown in FIG. 3A, (embodiment 300) a substrate, such as conductive substrate 350, may be exposed to a first gaseous precursor, such as precursor AX of expression (6a), which may comprise nickel dicyclopentadienyl (Ni(Cp)₂) although claimed subject matter is not limited in this respect. Exposure of conductive substrate 350 may occur for a duration approximately in the range of 0.5 seconds to 180.0 seconds. The sub-process of FIG. 3A may take place in a heated chamber which may attain, for example, a temperature approximately in the range of 20.0° C. to 400.0° C. However, it should be noted that additional temperature ranges, such as temperature ranges comprising less than approximately 20.0° C. and greater than approximately 400.0° C. are possible, and claimed subject matter is not limited in this respect. It should also be noted that additional ranges of atomic concentrations for Ni(Cp)₂ may be utilized, and claimed subject matter is not limited in this respect.

As shown in FIG. 3A, and as previously alluded to in the description of the embodiment of FIG. 2A, exposure of a conductive substrate, such as conductive substrate 350, to gaseous (Ni(Cp)₂ may result in adsorption of (Ni(Cp)₂ at various locations at the surface of substrate 350. Thus, as shown in FIG. 3A, Ni atoms may form metal-to-metal bonds with at least some Pt atoms of conductive substrate 350, such as Pt atom 352. However, also as shown in FIG. 3A, Cp ligands may operate to shield or otherwise obstruct access by gaseous precursors to a significant percentage of atoms of a conductive substrate, such as Pt atoms 354. Additionally, increasing a concentration of a precursor gas, such as (Ni(Cp)₂, may not bring about increased metal-to-metal bonding Ni and Pt atoms.

As shown in FIG. 3B, (embodiment 301) after exposure of a conductive substrate, such as conductive substrate 350, to a gaseous precursor, such as a gaseous precursor comprising (Ni(Cp)₂), the chamber may be purged of remaining gaseous Ni(Cp)₂ and/or unattached Cp ligands. In an embodiment, for the example of a gaseous precursor comprising (Ni(Cp)₂), the chamber may be purged for a duration approximately in the range of 0.5 seconds to 180.0 seconds. In one or more embodiments, a purge duration may depend, for example, on affinity (aside from chemical bonding) of unreacted ligands and byproducts with a noble metal utilized to form conductive substrate 350. In other embodiments, purge duration may depend, for example, on gas flow within the chamber. For example, gas flow within a chamber that is predominantly laminar may permit removal of remaining gaseous ligands at a faster rate, while gas flow within a chamber that is predominantly turbulent may give rise to removal of remaining ligands at a slower rate. It should be noted that claimed subject matter is intended to embrace purging of remaining gaseous material without regard to flow characteristics within a fabrication chamber.

As shown in FIG. 3C, (embodiment 302) a gaseous reducing agent may be introduced into the chamber. A gaseous reducing agent, such as H₂, may operate to chemically reduce ligands, such as Cp, for example, to give rise to detachment of ligands from metal atoms such as, for example, Ni. Accordingly, as shown in FIG. 3D, after exposure of conductive substrate 350 to gaseous H₂, unattached Cp molecules as well as unreacted reducing agent, such as H₂, may be purged from a chamber. Accordingly, after such purging, unoxidized Ni atoms may remain bonded or otherwise attached to atoms of a metallic species comprising conductive substrate 350. Expression (7), below, summarizes a reduction reaction of Ni(Cp)₂ with a gaseous reducing agent (H₂) for particular embodiments:

Ni(Cp)₂+H₂→Ni₍ₘₑₜₐₗ₎+Cp_{(gas)} (7)

It should be noted that although gaseous H₂ may be employed as a reducing agent, other gaseous reducing agents may be utilized in place of or in addition to H₂, and claimed subject matter is not limited in this respect. Additionally, although Ni(Cp)₂ has been employed as a gaseous precursor, additional metal ligand combinations may be utilized, and claimed subject matter is not limited in this respect.

As shown in FIG. 3E, (embodiment 304) conductive substrate 350 may be exposed to additional gaseous precursor, such as Ni(Cp)₂. Exposure to additional gaseous precursor may give rise to bonding of Ni(Cp)₂, for example, to previously unbonded Pt atoms, such as Pt atoms 354. As shown in FIG. 3E, previously unbonded Pt atoms 354 may be situated between sites at which Ni—Pt bonds have already occurred such as, for example, in response to the sub-process of embodiment 300 (FIG. 3A). Accordingly, exposure of conductive substrate 350 to additional gaseous precursor may bring about additional bonding of Pt atoms to Ni atoms of a gaseous precursor. Exposure of conductive substrate 350 may occur for a duration of approximately in the range of 0.5 seconds to 180.0 seconds and may take place in a heated chamber which may attain, for example, a temperature approximately in the range of 20.0° C. to 400.0° C.

As shown in FIG. 3F, (embodiment 305) a gaseous reducing agent, such as H₂, may again be introduced into a fabrication chamber, which may operate to chemically reduce ligands, such as Cp, for example, to permit detachment of ligands from metal atoms such as, for example, Ni. Accordingly, as shown in FIG. 3F, responsive to one or more additional exposures of conductive substrate 350 to gaseous H₂, unattached ligand molecules (e.g., Cp), as well as unreacted reducing agent (e.g., H₂), may be purged from a chamber, as shown in FIG. 3G. Accordingly, after such purging, unoxidized Ni atoms may remain bonded or otherwise attached to atoms of a metallic species comprising conductive substrate 350.

In particular embodiments, one or more of sub processes 300-306 (FIGS. 3A-3G) may be repeated so as to bring about coverage of a conductive substrate with a monolayer of a conductive metallic nucleation layer. As the term is used herein, a “monolayer” means a layer of material, such as a conductive material, formed on a surface of a substrate such that there is an absence of exposed portions of the surface of the substrate. An example of a monolayer may comprise a layer in which there is an approximately 1.0:1.0 ratio between atoms present at a surface of a conductive substrate and atoms of a layer deposited on the surface of the conductive substrate. In one example, a monolayer comprising an atomic concentration of approximately 50.0% of a transition metal oxide, such as Ni, may be deposited over a conductive substrate comprising, for example, an atomic concentration of at least 50.0% of a noble metal or may be deposited over a conductive metal oxide comprising an atomic concentration of at least 50.0% metal. In a particular embodiment of FIG. 3G, a number of Pt atoms of conductive substrate 350 are indicated as comprising metal-to-metal bonds with a corresponding number of Ni atoms. It should be noted, however, that in certain embodiments, a nucleation layer may comprise a “sub-monolayer. In this context, a “sub-monolayer” means a layer of material formed on a surface of a substrate, wherein at least a portion of the surface is exposed or otherwise uncovered by the material. An example of a sub-monolayer may comprise a layer in which there is less than an approximately 1.0:1.0 ratio between atoms of a layer deposited on the surface of a conductive substrate and atoms of a surface of the conductive substrate. In one example, a sub-monolayer comprising an atomic concentration of approximately 50.0% Ni may be deposited on a conductive substrate comprising, for example, an atomic concentration of at least 50.0% of a noble metal such as, for example, atoms of conductive substrate 350. In such instances, formation of a sub-monolayer of metallic nucleation sites may still operate to permit fabrication of a CEM film deposited using, for example, an atomic layer deposition approach.

In embodiments, responsive to one or more cycles of exposure of the conductive substrate to a gaseous precursor followed by exposure to a gaseous reducing agent, nucleation layer 375 may be formed on the conductive substrate, such as conductive substrate 350. Nucleation layer 375, which may comprise a monolayer or sub-monolayer, may be oxidized, for example, utilizing oxygen (O₂), ozone (O₃), for example, and/or may be exposed to a molecular dopant, such as carbonyl (CO). In embodiments, nucleation layer 375 may represent a more reactive layer than the noble metal of conductive substrate 350. Accordingly, processes utilized to fabricate a CEM film, such as, for example, atomic layer deposition as described with reference to expressions (6a) and (6b) may be employed utilizing transition metals or transition metal oxides, or a combination thereof.

It should be noted that, in particular embodiments, a nucleation layer, such as nucleation layer 375, may actually comprise more than one physical layer of atoms of a transition metal. For example, nucleation layer 375 may comprise regions having an uneven thickness of a transition metal, for example, such as Ni. Thus, certain areas of nucleation layer 375 may comprise a thickness of greater than a single layer of Ni atoms bonded to atoms of a conductive substrate, while other areas of nucleation layer 375 may comprise a monolayer or sub-monolayer of Ni atoms bonded to atoms of a conductive substrate. In particular embodiments, nucleation layer 375 may comprise a thickness approximately in the range of 2.0 Å to 200.0 Å. In certain embodiments, nucleation layer 375 may comprise a thickness approximately in the range of 5.0 Å to 25.0 Å, although claimed subject matter is intended to embrace nucleation layers thinner than approximately 2.0 Å, for example, and thicker than approximately 200.0 Å.

In particular embodiments, after fabrication of a CEM film on or over nucleation layer 375, and prior to fabrication of a conductive overlay, such as conductive overlay 180 of FIG. 1B, a second nucleation layer may be formed. In particular embodiments, forming a second nucleation layer on a CEM may permit subsequent deposition of a conductive overlay comprising a large proportion of a noble metal, which may be resistant to forming bonds with a transition metal oxides of the CEM. Forming a second nucleation layer 375 may involve introduction of one or more gaseous reducing agents, such as H₂, during fabrication of one or more final layers of a CEM film rather than utilizing an oxidizer, such as oxygen (O₂), ozone (O₃), nitric oxide (NO), hydrogen peroxide (H₂O₂), for example, in an atomic layer deposition process. In one possible example, a second nucleation layer 375 comprising a thickness approximately in the range of 2.0 Å to 200.0 Å may be formed during final steps of forming a CEM film followed by deposition process to form a conductive overlay comprising a large proportion of platinum.

It should be noted that although FIGS. 2A-2C and FIGS. 3A-3G have been described as utilizing a nickel-based nucleation layer as well as a nickel-based CEM (e.g., NiO), in other embodiments, a nucleation layer and a CEM need not utilize identical metallic species. Thus, in embodiments, a nucleation layer, such as nucleation layer 375, for example, may comprise Ni, and a CEM may be formed from an entirely different metallic species, such as aluminum, cadmium, chromium, cobalt, copper, gold, iron, manganese, mercury, molybdenum, palladium, rhenium, ruthenium, silver, tantalum, tin, titanium, vanadium yttrium, and zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

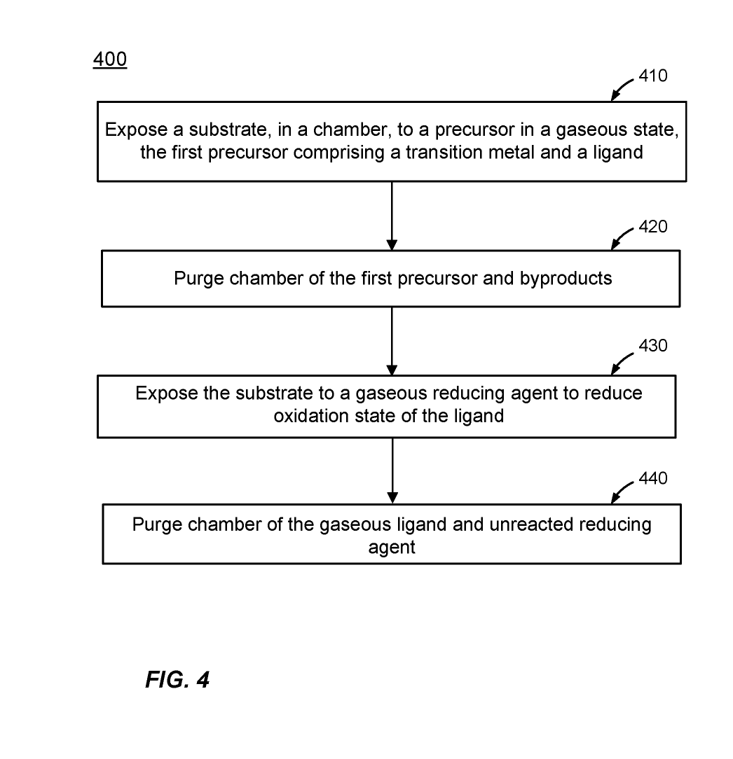

FIG. 4 is a flow diagram of an embodiment 400 for a process of forming a nucleation layer on a conductive substrate. Example implementations, such as described in FIG. 4, may include blocks in addition to those shown and described, fewer blocks, or blocks occurring in an order different than may be identified, or any combination thereof. The process may begin at block 410 in which a substrate, such as a conductive substrate, may be exposed in a chamber to a precursor in a gaseous state. In particular embodiments, the first precursor may comprise a transition metal, such as Ni, and a first ligand, such as (Cp)₂, for example. At block 420, a process chamber may be purged of unreacted precursor such as, for example, (Cp)₂. At block 430, a substrate, such as a conductive substrate, may be exposed to a gaseous reducing agent, such as H₂, which may operate to reduce the oxidation state of the ligand. In particular embodiments, a reduction of an oxidation state of a ligand, such as (Cp)₂ may bring about detachment of the ligand from, for example, a transition metal atom, such as Ni, which may allow the detached ligand to comprise a gaseous form. At block 440, a process chamber may be purged of the gaseous ligand and unreacted reducing agent, such as H₂.

In embodiments, performing the method of blocks 410-440 may be repeated to bring about at least a sub-monolayer or monolayer of metallic nucleation sites. In embodiments, a sub-monolayer or monolayer of metallic nucleation sites may provide a sufficiently reactive surface, which may permit formation of a CEM film using an atomic layer deposition approach, for example, on or over the sub-monolayer or monolayer of metallic nucleation sites. In embodiments, metallic nucleation sites may be unevenly distributed across a conductive substrate such that certain areas, for example, may comprise additional layers of a transition metal, while other areas of a conductive substrate comprise a monolayer or sub-monolayer of a transition metal, for example. In addition, block 410-440 may be performed prior to depositing a conductive overlay so as to provide a nucleation layer devoid of oxides of a transition metal, for example. Responsive to providing a nucleation layer devoid of oxides, a conductive substrate comprising a large proportion of an oxide-resistant noble metal, may be deposited on the nucleation layer.

It should be pointed out that although atomic layer deposition has been identified as an approach toward fabricating a CEM films, claimed subject matter may embrace a wide variety of CEM fabrication processes such as, for example, a metal oxide chemical vapor deposition, physical vapor deposition, or other fabrication process.

In embodiments, CEM devices may be implemented in any of a wide range of integrated circuit types. For example, numerous CEM devices may be implemented in an integrated circuit to form a programmable memory array, for example, that may be reconfigured by changing impedance states for one or more CEM devices, in an embodiment. In another embodiment, programmable CEM devices may be utilized as a non-volatile memory array, for example. Of course, claimed subject matter is not limited in scope to the specific examples provided herein.

A plurality of CEM devices may be formed to bring about integrated circuit devices, which may include, for example, a first correlated electron device having a first correlated electron material and a second correlated electron device having a second correlated electron material, wherein the first and second correlated electron materials may comprise substantially dissimilar impedance characteristics that differ from one another. Also, in an embodiment, a first CEM device and a second CEM device, comprising impedance characteristics that differ from one another, may be formed within a particular layer of an integrated circuit. Further, in an embodiment, forming the first and second CEM devices within a particular layer of an integrated circuit may include forming the CEM devices at least in part by selective epitaxial deposition. In another embodiment, the first and second CEM devices within a particular layer of the integrated circuit may be formed at least in part by ion implantation, such as to alter impedance characteristics for the first and/or second CEM devices, for example.

Also, in an embodiment, two or more CEM devices may be formed within a particular layer of an integrated circuit at least in part by atomic layer deposition of a correlated electron material. In a further embodiment, one or more of a plurality of correlated electron switch devices of a first correlated electron switch material and one or more of a plurality of correlated electron switch devices of a second correlated electron switch material may be formed, at least in part, by a combination of blanket deposition and selective epitaxial deposition. Additionally, in an embodiment, first and second access devices may be positioned substantially adjacently to first and second CEM devices, respectively.

In a further embodiment, one or more of a plurality of CEM devices may be individually positioned within an integrated circuit at one or more intersections of electrically conductive lines of a first metallization layer and electrically conductive lines of a second metallization layer, in an embodiment. One or more access devices may be positioned at a respective one or more of the intersections of the electrically conductive lines of the first metallization layer and the electrically conductive lines of the second metallization layer, wherein the access devices may be paired with respective CEM devices, in an embodiment.

In the preceding description, in a particular context of usage, such as a situation in which tangible components (and/or similarly, tangible materials) are being discussed, a distinction exists between being “on” and being “over.” As an example, deposition of a substance “on” a substrate refers to a deposition involving direct physical and tangible contact without an intermediary, such as an intermediary substance (e.g., an intermediary substance formed during an intervening process operation), between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact, but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under” are understood in a similar manner as the terms “up,” “down,” “top,” “bottom,” and so on, previously mentioned. These terms may be used to facilitate discussion, but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes a flip chip, as one illustration, in which, for example, orientation at various times (e.g., during fabrication) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second,” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques, even if those reasonable alternative techniques do not provide identical values, identical measurements or identical results, unless otherwise expressly indicated.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be predominantly present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present disclosure merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

In the preceding description, various aspects of claimed subject matter have been described. For purposes of explanation, specifics, such as amounts, systems, and/or configurations, as examples, were set forth. In other instances, well-known features were omitted and/or simplified so as not to obscure claimed subject matter. While certain features have been illustrated and/or described herein, many modifications, substitutions, changes, and/or equivalents will occur to those skilled in the art. It is, therefore, to be understood that the appended claims are intended to cover all modifications and/or changes as fall within claimed subject matter.

1. A correlated electron material (CEM) device, comprising:
a conductive substrate comprising an atomic concentration of at least one noble metal or a material formed from an oxide of at the least one noble metal sufficient to bring about predominantly conductive behavior of the conductive substrate; and
a first nucleation layer, formed on a surface of the conductive substrate, to permit deposition of one or more layers of a CEM film over the conductive substrate, the first nucleation layer comprising reduced oxide nickel.

2. The CEM device of claim 1, further comprising:
a second nucleation layer, formed on a surface of the CEM film, the second nucleation layer to permit deposition of a conductive overlay on the second nucleation layer.

3. The CEM device of claim 1, wherein the CEM film comprises a dopant concentration of between 0.1% and 15.0%, and wherein the first nucleation layer comprises an atomic concentration of at least 50.0% of a metallic species forming the CEM film.

4. The CEM device of claim 1, wherein the first nucleation layer is formed from a metallic species identical to the metallic species of the CEM film.

5. The CEM device of claim 1, wherein the first nucleation layer comprises a monolayer formed over the surface of the conductive substrate.

6. The CEM device of claim 1, wherein the first nucleation layer comprises a sub-monolayer formed over the surface of the conductive substrate.

7. The CEM device of claim 1, wherein the first nucleation layer comprises a thickness in a range of 2.0 Å to 200.0 Å.

8. The CEM device of claim 1, wherein the first nucleation layer comprises a thickness in a range of 5.0 Å to 25.0 Å.

9. The CEM device of claim 1, wherein the first nucleation layer comprises a conductive material.

10. The CEM device of claim 1, wherein the atomic concentration of the conductive substrate comprises at least 50.0% of the at least one noble metal or the oxide of the at least one noble metal.

11. A method of constructing a correlated electron material (CEM) device, comprising:
forming, in a chamber, a conductive substrate comprising an atomic concentration of a noble metal, an alloy of two or more noble metals, or a material formed from an oxide of at least one noble metal sufficient to bring about predominantly conductive behavior of the substrate;
forming one or more first nucleation layers on the conductive substrate; and
forming a CEM film on the one or more nucleation layers.

12. The method of claim 11, further comprising:
forming one or more second nucleation layers on the CEM film; and
forming a conductive overlay over the one or more second nucleation layers.

13. The method of claim 11, wherein forming the CEM film on the one or more nucleation layers comprises depositing one or more layers of CEM via an atomic layer deposition process.

14. The method of claim 11, wherein the one or more first nucleation layers comprise a conductive material comprising a transition metal or transition metal oxide having an atomic concentration of at least approximately 50.0%.

15. The method of claim 11, wherein the one or more first nucleation layers comprise a sub-monolayer of a conductive material comprising an atomic concentration of at least approximately 50.0% noble metal or a noble metal oxide comprising at least 50.0% metal.

16. The method of claim 11, wherein forming the conductive substrate comprises depositing one or more layers having an atomic concentration at least approximately 50.0% of the noble metal, or the noble metal alloy, or the oxide of the at least one noble metal sufficient to bring about predominantly conductive behavior of the substrate.

17. An electronic device, comprising:
a correlated electron material (CEM) film disposed between a conductive substrate and a conductive overlay;
a first nucleation layer formed between a first side of the CEM film and the conductive substrate; and
a second nucleation layer formed between a second side of the CEM film and the conductive overlay, wherein
the conductive substrate and the conductive overlay comprise an atomic concentration of at least one noble metal or a material formed from an oxide of at the least one noble metal sufficient to bring about predominantly conductive behavior of the conductive substrate and the conductive overlay, and wherein
the first nucleation layer or the second nucleation layer comprising reduced oxide nickel.

18. The electronic device of claim 17, wherein the first nucleation layer or the second nucleation layer, or a combination thereof, comprises a sub-monolayer.

19. The electronic device of claim 17, wherein the first nucleation layer or the second nucleation layer, or a combination thereof, form a monolayer.

20. The electronic device of claim 17, wherein the CEM film comprises a P-type dopant in an atomic concentration of between 0.1% and 15.0%.

21. The electronic device of claim 17, wherein the first nucleation layer comprises a thickness in a range of 5.0 Å to 25.0 Å.

22. The electronic device of claim 17, wherein the atomic concentration of the conductive substrate and the conductive overlay comprise at least 50.0%.

23. The CEM device of claim 1, wherein the first nucleation layer comprises a transition metal substantially devoid of oxides.

24. The electronic device of claim 17, wherein the first nucleation layer or the second nucleation layer comprises a transition metal substantially devoid of oxides.
